(19) United States
(12) Patent Application Publication
(10) Pub. No.: US 2025/0376415 A1
(43) Pub. Date: Dec. 11, 2025

(54) Fibrous Core-Shell Silicon-Carbon Structures

(71) Applicant: The Regents of the University of California, Oakland, CA (US)

(72) Inventors: Timothy Scott Fisher, Los Angeles, CA (US); Mostafa M. Abuseada, Culver City, CA (US)

(73) Assignee: The Regents of the University of California, Oakland, CA (US)

(21) Appl. No.: 18/876,618

(22) PCT Filed: Aug. 11, 2023
(86) PCT No.: PCT/US2023/072082

§ 371 Date: Dec. 18, 2024

Related U.S. Application Data
(60) Provisional application No. 63/371,356, filed on Aug. 12, 2022.

(51) Int. Cl. C03C 25/44; C03C 25/223; C03C 25/622; H01M 4/02; H01M 4/04; H01M 4/36; H01M 4/38; H01M 4/48; H01M 4/583; H01M 10/0525

(52) U.S. Cl. CPC C03C 25/44; C03C 25/223; C03C 25/622; H01M 4/0428; H01M 4/366; H01M 4/386; H01M 4/48; H01M 4/583; H01M 10/0525; H01M 2004/027

(57) ABSTRACT

This disclosure relates to novel lithium ion battery structures and methods of manufacture. One particular method includes a method of coating a porous glass substrate. The method includes: providing a porous glass substrate; flowing gaseous hydrocarbon onto a porous glass substrate in a reaction zone; and exposing the porous glass substrate to a concentrated solar irradiation in the reaction zone such that the porous substrate and gases surrounding the porous substrate absorb the concentrated solar irradiation producing heat. The heat chemically reduces glass fibers in the porous glass substrate into silicon fibers, and the heat decomposes the gaseous hydrocarbon into a carbon coating on the silicon fibers.

### CROSS-REFERENCE TO RELATED APPLICATIONS

This application claims the benefit of and priority under 35 U.S.C. § 119 (e) to U.S. Provisional Patent Application Ser. No. 63/371,356 entitled “Fibrous Core-Shell Silicon-Graphite,” filed Aug. 12, 2022, which is incorporated herein by reference in its entirety for all purposes.

### FIELD OF THE DISCLOSURE

The present invention generally relates to fibrous core silicon-carbon structures and methods of producing thereof.

### BACKGROUND

High rates of charging are desirable for fast charging of electric vehicles and similar battery-powered devices. Fast discharging may also be desired in some applications, although the demand for fast charging may be much more challenging technically. Silicon-based anode materials in battery technology has previously been utilized. A major advantage of silicon-based (including silica) anode material is its high lithium uptake capacity (e.g., up to approximately 10× more than graphite per unit weight). Silicon-based anodes may include silicon-based particles of approximately 100-1000 nanometer diameter. However, a major limitation and disadvantage of particulate silicon-based anode material is its very low thermal conductivity. Also, a major limitation and disadvantage of silicon-based anode material is its very low electrical conductivity. Thus, increases in thermal and electrical conductivity in silicon-based anodes in Li-ion batteries may be advantageous.

### SUMMARY OF THE DISCLOSURE

In some aspects, the techniques described herein relate to a method of coating a porous glass substrate, the method including: providing a porous glass substrate; flowing gaseous hydrocarbon onto a porous glass substrate in a reaction zone; and exposing the porous glass substrate to a concentrated solar irradiation in the reaction zone such that the porous substrate and gases surrounding the porous substrate absorb the concentrated solar irradiation producing heat, wherein the heat chemically reduces glass fibers in the porous glass substrate into silicon fibers, and wherein the heat decomposes the gaseous hydrocarbon into a carbon coating on the silicon fibers.

In some aspects, the techniques described herein relate to a method, wherein the heat decomposes the gaseous hydrocarbon into hydrogen gas and carbon.

In some aspects, the techniques described herein relate to a method, wherein the concentrated solar irradiation causes photocatalysis which accelerates the decomposition of the gaseous hydrocarbon into hydrogen gas and carbon.

In some aspects, the techniques described herein relate to a method, wherein the concentrated solar irradiation has a concentration factor of 100 or greater.

In some aspects, the techniques described herein relate to a method, wherein the gaseous hydrocarbon is high purity methane gas.

In some aspects, the techniques described herein relate to a method, wherein the gaseous hydrocarbon is a biogas.

In some aspects, the techniques described herein relate to a method, wherein the gaseous hydrocarbon includes a carrier gas mixed with methane or biogas.

In some aspects, the techniques described herein relate to a method, wherein the carrier gas is hydrogen gas, nitrogen gas, and/or argon gas.

In some aspects, the techniques described herein relate to a method, wherein the carbon includes graphene, graphite, carbon nanotubes, or carbon black which is deposited conformally onto the surfaces of the silicon fibers.

In some aspects, the techniques described herein relate to a method, wherein the conformal carbon coating from adjacent elements or ligaments of the porous substrate coalesce to form a continuous structure.

In some aspects, the techniques described herein relate to a method, wherein, after the carbon is deposited onto the porous substrate, the porous substrate is used to manufacture electrochemical energy storage devices.

In some aspects, the techniques described herein relate to a method, wherein the concentrated solar irradiation includes solar light from the sun.

In some aspects, the techniques described herein relate to a method, wherein the concentrated solar irradiation includes solar light from the sun augmented with an artificial light source.

In some aspects, the techniques described herein relate to a method, further including optimizing the amount of augmented artificial light from the artificial light source to keep a constant amount of irradiation.

In some aspects, the techniques described herein relate to a method, wherein the artificial light source includes a plasma arc lamp, a halogen bulb, an LED, a fluorescent bulb, metal halide lamp, or argon lamp.

In some aspects, the techniques described herein relate to a method, wherein the artificial light source includes a xenon arc lamp.

In some aspects, the techniques described herein relate to a method, wherein the concentrated solar irradiation includes the solar light from the sun during a time when the sun is irradiating light into concentrators that concentrate the sun light into the reaction zone and the concentrated solar irradiation includes artificial light when the sun is not irradiating light into the concentrators.

In some aspects, the techniques described herein relate to a method, wherein the concentrated solar irradiation includes light from an artificial light source.

In some aspects, the techniques described herein relate to a method, wherein the porous glass substrate includes a roll to roll substrate.

In some aspects, the techniques described herein relate to a method, further including operating the roll to roll substrate to continually maintain fresh porous glass substrate.

In some aspects, the techniques described herein relate to a method, wherein the porous glass substrate includes silica cloth or felt.

In some aspects, the techniques described herein relate to a method, further including concentrating a solar light source using a reflector.

In some aspects, the techniques described herein relate to a method, wherein the reflector includes an elliptical reflector, a parabolic reflector, a compound reflector, a Fresnel lens, and/or an array of flat reflectors.

In some aspects, the techniques described herein relate to a method, wherein the reflector includes a variable reflector which adjusts the amount of concentrated solar irradiation in the reaction zone.

In some aspects, the techniques described herein relate to a method, wherein the reaction zone is housed within a reaction chamber.

In some aspects, the techniques described herein relate to a method, wherein the exposing the gaseous hydrocarbon to the concentrated solar irradiation occurs in multiple directions.

In some aspects, the techniques described herein relate to a method, wherein the gaseous hydrocarbon includes natural gas.

In some aspects, the techniques described herein relate to a method, further including: reflowing an output gas onto the porous glass substrate in the reaction zone; and exposing the porous glass substrate to a concentrated solar irradiation in the reaction zone such that the reflowed gas further decomposes into hydrogen gas and carbon.

In some aspects, the techniques described herein relate to a method, further including pre-processing the porous glass substrate by adhering silicon or glass particles to the glass fibers, wherein the silicon or glass particles are incorporated into the carbon coating on the silicon fibers after exposure to the concentrated solar irradiation.

In some aspects, the techniques described herein relate to a method, wherein the silicon or glass particles are nano-particles or micro-particles.

In some aspects, the techniques described herein relate to a method, wherein the carbon coating includes cylindrical concentric layers of carbon which are concentrically layered on top of one another in a repeating pattern.

In some aspects, the techniques described herein relate to a method, wherein the silicon fibers include silicon dioxide and silicon.

In some aspects, the techniques described herein relate to a method, wherein the silicon fibers include a silicon dioxide core with a silicon annulus surrounding the silicon dioxide core.

In some aspects, the techniques described herein relate to a method, wherein the silicon annulus forms a shell around the silicon dioxide core.

In some aspects, the techniques described herein relate to a method, wherein the silicon fibers include solid silicon fibers.

In some aspects, the techniques described herein relate to a method of coating a porous glass substrate, the method including: providing a porous glass substrate; flowing a carrier gas onto a porous glass substrate in a reaction zone; exposing the porous glass substrate to a concentrated solar irradiation in the reaction zone such that the porous substrate and gases surrounding the porous substrate absorb the concentrated solar irradiation producing heat, wherein the heat chemically reduces glass fibers in the porous glass substrate into silicon fibers; as the reduction reaction ceases: flowing a gaseous hydrocarbon onto the silicon fibers; and exposing the silicon fibers to the concentrated solar irradiation such that the silicon fibers and the gases surrounding the silicon fibers absorb the concentrated solar irradiation to produce heat, wherein the heat decomposes the gaseous hydrocarbon into a carbon coating on the silicon fibers.

In some aspects, the techniques described herein relate to a method, wherein the heat decomposes the gaseous hydrocarbon into hydrogen gas and carbon.

In some aspects, the techniques described herein relate to a method, wherein the concentrated solar irradiation causes photocatalysis which accelerates the decomposition of the gaseous hydrocarbon into hydrogen gas and carbon.

In some aspects, the techniques described herein relate to a method, wherein the concentrated solar irradiation has a concentration factor of 100 or greater.

In some aspects, the techniques described herein relate to a method, wherein the gaseous hydrocarbon is high purity methane gas.

In some aspects, the techniques described herein relate to a method, wherein the gaseous hydrocarbon is a biogas.

In some aspects, the techniques described herein relate to a method, wherein the gaseous hydrocarbon includes a carrier gas mixed with methane or biogas.

In some aspects, the techniques described herein relate to a method, wherein the carrier gas is hydrogen gas.

In some aspects, the techniques described herein relate to a method, wherein the carbon includes graphene, graphite, carbon nanotubes, or carbon black which is deposited conformally onto the surfaces of the silicon fibers.

In some aspects, the techniques described herein relate to a method, wherein the conformal carbon coating from adjacent elements or ligaments of the porous substrate coalesce to form a continuous structure.

In some aspects, the techniques described herein relate to a method, wherein, after the carbon is deposited onto the porous substrate, the porous substrate is used to manufacture electrochemical energy storage devices.

In some aspects, the techniques described herein relate to a method, wherein the porous substrate is used to manufacture an anode of a lithium ion battery.

In some aspects, the techniques described herein relate to a method, wherein the concentrated solar irradiation includes solar light from the sun.

In some aspects, the techniques described herein relate to a method, wherein the concentrated solar irradiation includes solar light from the sun augmented with an artificial light source.

In some aspects, the techniques described herein relate to a method, further including optimizing the amount of augmented artificial light from the artificial light source to keep a constant amount of irradiation.

In some aspects, the techniques described herein relate to a method, wherein the artificial light source includes a plasma arc lamp, a halogen bulb, an LED, a fluorescent bulb, metal halide lamp, or argon lamp.

In some aspects, the techniques described herein relate to a method, wherein the artificial light source includes a xenon arc lamp.

In some aspects, the techniques described herein relate to a method, wherein the concentrated solar irradiation includes the solar light from the sun during a time when the sun is irradiating light into concentrators that concentrate the sun light into the reaction zone and the concentrated solar irradiation includes artificial light when the sun is not irradiating light into the concentrators.

In some aspects, the techniques described herein relate to a method, wherein the concentrated solar irradiation includes light from an artificial light source.

In some aspects, the techniques described herein relate to a method, wherein the porous glass substrate includes a roll to roll substrate.

In some aspects, the techniques described herein relate to a method, further including operating the roll to roll substrate to continually maintain fresh porous glass substrate.

In some aspects, the techniques described herein relate to a method, wherein the porous glass substrate includes silica cloth or felt.

In some aspects, the techniques described herein relate to a method, further including concentrating a solar light source using a reflector.

In some aspects, the techniques described herein relate to a method, wherein the reflector includes an elliptical reflector, a parabolic reflector, a compound reflector, a Fresnel lens, and/or an array of flat reflectors.

In some aspects, the techniques described herein relate to a method, wherein the reflector includes a variable reflector which adjusts the amount of concentrated solar irradiation in the reaction zone.

In some aspects, the techniques described herein relate to a method, wherein the reaction zone is housed within a reaction chamber.

In some aspects, the techniques described herein relate to a method, wherein the exposing the gaseous hydrocarbon to the concentrated solar irradiation occurs in multiple directions.

In some aspects, the techniques described herein relate to a method, wherein the gaseous hydrocarbon includes natural gas.

In some aspects, the techniques described herein relate to a method, further including: reflowing an output gas onto the porous glass substrate in the reaction zone; and exposing the porous glass substrate to a concentrated solar irradiation in the reaction zone such that the reflowed gas further decomposes into hydrogen gas and carbon.

In some aspects, the techniques described herein relate to a method, further including pre-processing the porous glass substrate by adhering silicon or glass particles to the glass fibers, wherein the silicon or glass particles are incorporated into the carbon coating on the silicon fibers after exposure to the concentrated solar irradiation.

In some aspects, the techniques described herein relate to a method, wherein the silicon or glass particles are nano-particles or micro-particles.

In some aspects, the techniques described herein relate to a method, wherein the carbon coating includes cylindrical concentric layers of carbon which are concentrically layered on top of one another in a repeating pattern.

In some aspects, the techniques described herein relate to a method, wherein the silicon fibers include silicon dioxide and silicon.

In some aspects, the techniques described herein relate to a method, wherein the silicon fibers include a silicon dioxide core with a silicon shell.

In some aspects, the techniques described herein relate to a method, wherein the silicon fibers include solid silicon fibers.

In some aspects, the techniques described herein relate to an anode for a lithium ion battery including a plurality of silicon fibers which are coated by a carbon coating.

In some aspects, the techniques described herein relate to an anode, wherein the silicon fibers include silicon dioxide and silicon.

In some aspects, the techniques described herein relate to an anode, wherein the silicon fibers include a silicon dioxide core with a silicon annulus surrounding the silicon dioxide core.

In some aspects, the techniques described herein relate to an anode, wherein the silicon annulus forms a shell around the silicon dioxide core.

In some aspects, the techniques described herein relate to an anode, wherein a silicon-carbide material is at the interface between the silicon fibers and the carbon coating.

In some aspects, the techniques described herein relate to an anode, wherein the carbon coating includes silicon or glass particles.

In some aspects, the techniques described herein relate to an anode, wherein the silicon or glass particles are nano-particles or micro-particles.

In some aspects, the techniques described herein relate to an anode, wherein the silicon fibers include solid silicon fibers.

In some aspects, the techniques described herein relate to an anode, wherein the carbon coating includes cylindrical concentric layers of carbon which are concentrically layered on top of one another in a repeating pattern.

In some aspects, the techniques described herein relate to an anode, wherein the silicon fibers include amorphous silicon.

In some aspects, the techniques described herein relate to a lithium ion battery including: an anode; and a cathode separated from the anode, the anode is the anode disclosed above.

### BRIEF DESCRIPTION OF THE DRAWINGS

The description will be more fully understood with reference to the following figures and data graphs, which are presented as various embodiment of the disclosure and should not be construed as a complete recitation of the scope of the disclosure.

FIG. 1 schematically illustrates a process for graphitic deposition on a core of silicon in accordance with an embodiment of the invention.

FIG. 2 is a flowchart illustrating an example process for producing silicon fibers coated with graphite in accordance with an embodiment of the invention.

FIG. 3 is a schematic cross-sectional view of an example silicon fiber coated with graphite in accordance with an embodiment of the invention.

FIG. 4 is a scanning electron microscope (SEM) image of a processed porous glass substrate.

FIGS. 5A, 5B, and 5C illustrate various energy dispersed spectroscopy (EDS) images of the processed porous glass substrate illustrated in FIG. 4.

FIG. 6 is two example X-ray diffraction (XRD) plot on the processed porous glass substrate illustrated in FIG. 4 and the unprocessed porous glass substrate.

FIG. 7 illustrates an example schematic of glass fibers before carbon deposition which have been pre-processed by glass or silicon particles in accordance with an embodiment of the invention.

FIG. 8 schematically illustrates an example battery in accordance with an embodiment of the invention.

### DETAILED DESCRIPTION

It has been discovered that the addition of carbon-based coatings to silicon-based anode materials in battery technology may provide increased thermal and electrical conductivity while also providing additional ion storage capacity. The carbon-based coatings allow for fast charging without producing excessive Joule heating that can cause thermal runaway, which may lead to excessive temperatures and battery fires.

Various embodiments of this disclosure include a cylindrical core-shell structure with a shell of graphitic deposition and a protected core containing silicon. This structure may be highly advantageous for lithium ion (Li-ion) battery anodes, as silicon and graphite are known to have high lithium uptake capacities. In fact, the related charge storage capacity of silicon may be up to ten times greater than graphite. However, silicon suffers from poor mechanical stability and related cyclic storage limitations. The silicon may be protected from much of this mechanical degradation by the graphitic shell.

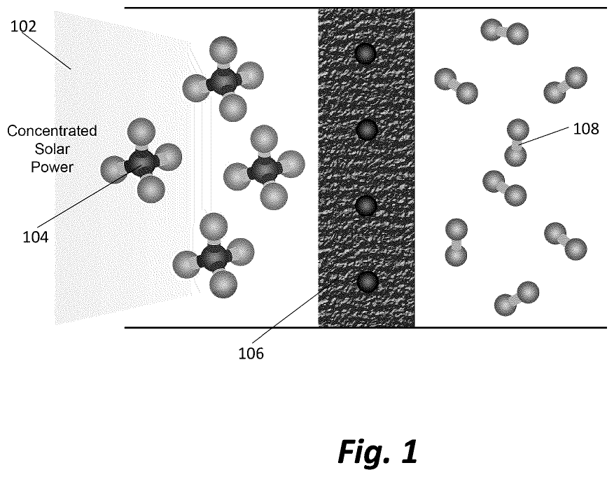

Turning to the drawings, FIG. 1 schematically illustrates a process for graphitic deposition on a core of silicon in accordance with an embodiment of the invention. A concentrated light 102 may be introduced to a gaseous hydrocarbon 104 which may disassociate the carbon and the hydrogen 108. The concentrated light 102 may be a concentrated solar light. The carbon may be trapped into a porous silicon dioxide (SiO₂) substrate 106 while the hydrogen 108 is left to flow out as hydrogen gas. In some embodiments, the porous SiO₂ substrate 106 may include silica cloth or felt. The porous SiO₂ substrate 106 may include a woven silica material with silica fibers. The silica fibers may be long cylindrical shaped fibers which extend and weave together. In some embodiments, the porous SiO₂ substrate 106 may be setup in a roll to roll process where fresh substrate may be continuously fed into a reaction chamber. The roll to roll process may be continuously operated.

In some examples, the porous starting SiO₂ substrate 106 may be pre-processed with glass or silicon particles before being coated with carbon. The particles may be nano-particles or micro-particles. The particles may be loosely attached to the fibers by Van der Waals forces. The chemical reduction and high temperatures may fuse (e.g. bond) them to the fibers. During the carbon coating process, the particles may be conformally coated with graphene, graphite, carbon nanotubes, and/or carbon black. The conformal carbon coating from adjacent elements or ligaments of the porous substrate may coalesce to form a continuous structure.

In some embodiments, the concentrated light 102 may be light from the sun which may be concentrated through one or more concentrators (e.g. reflectors, refractors, mirrors). The concentrators may include an elliptical reflector, a parabolic reflector, a compound reflector, a Fresnel lens, and/or an array of flat reflectors. The concentrators may be variable concentrators (e.g. variable mirrors) which may vary the amount of light applied to the flow of gaseous hydrocarbon 104. The gaseous hydrocarbon 104 may be methane gas. The disassociation of gaseous hydrocarbon 104 into carbon and hydrogen is an endothermic reaction. In some embodiments, the axis of the concentrated light 102 may be altered to alter the strength of the light depending on the optimal amount of light for a specific situation.

In some embodiments, the concentrated light 102 may be produced by an artificial light source such as a xenon light source, metal halide light source, or argon light source. In some embodiments, a combination of light from the sun and artificial light source may be used to perform the reaction. For example, the sun may produce the light during the day whereas at night, a light source may be used to perpetuate the reaction. Further, the reaction may strictly be performed using light from the artificial light source. Light from the artificial light source may approach the porous SiO₂ substrate 106 from one direction whereas light from the sun may approach from another direction. The gaseous hydrocarbon 104 (e.g. methane) may be a transparent gas which may not absorb a significant amount of gaseous hydrocarbon 104. The porous SiO₂ substrate 106 may absorb the concentrated light 102 within its solid web producing local heating of the gaseous hydrocarbon as it flows through the porous web and photocatalysis that accelerates the decomposition. The porous SiO₂ substrate 106 and the gases surrounding the porous SiO₂ substrate 106 may absorb the concentrated solar light 102 to produce heat which may decompose the gaseous hydrocarbon 104 into hydrogen gas and carbon. The gaseous hydrocarbon 104 and/or the porous SiO₂ substrate 106 may include no separate catalyst. The gaseous hydrocarbon 104 may also include a carrier gas such as hydrogen, nitrogen, and/or argon. The gaseous hydrocarbon 104 may include natural gas. It has been discovered that the carbon quality is enhanced with addition of a carrier gas such as hydrogen to the gaseous hydrocarbon 104.

The process of disassociation of the gaseous hydrocarbon 104 by heating may be referred to as cracking (e.g. hydrocarbon cracking or methane cracking). In some embodiments, an output gas may be reflowed onto the porous SiO₂ substrate in the reaction zone. The porous glass substrate may be further exposed to a concentrated solar irradiation in the reaction zone such that the reflowed gas further decomposes into hydrogen gas and carbon.

Methods and apparatus for deposition of graphitic carbon on a porous substrates are described in Int. Pub. No. 2022/236303, entitled “Apparatus and method for gaseous hydrocarbon self-catalyzation, reforming, and solid carbon deposition” and filed May 5, 2022 which is hereby incorporated by reference in its entirety for all purposes. This publication includes disclosure of a unique composite material including a rod-like core of silicon surrounded by a tube-like shell of graphite. This disclosure further includes a light emission device which produces controllable radiative heat flux up to 4500 suns, which may be sufficient to bring reactor operating temperatures above 1500 K. Similar conditions may be produced with a solar concentrator located outdoors in a natural insolation environment. In some embodiments, gaseous hydrocarbon (e.g. methane or biogas) flow may be directed and decomposed onto a porous SiO₂ fiber substrate (e.g., glass felt or woven cloth). The use of the porous substrate also works to significantly enhance heat transfer to the flowing medium as a result of the increased surface area, which thus increases the methane decomposition/conversion efficiency.

It has been discovered that, at the beginning of the reaction, the glass fibers within the porous glass fiber substrate chemically reduce, producing a product stream of predominantly water vapor, unreacted gaseous hydrocarbon, other intermediate hydrocarbons, and hydrogen, as well as solid silicon fibers (e.g., deoxygenated glass fibers). Thus, the SiO₂ fibers which make up the porous SiO₂ fiber substrate are stripped of their oxygen leaving predominantly silicon fibers. Thereafter, the reduction reaction ceases due to the absence of accessible oxygen, and the overall reaction changes to methane decomposition, producing predominantly hydrogen gas and solid carbon deposition on the surface of the resultant silicon fibers.

In some embodiments, the starting substrate may be a porous silicon substrate. The silicon substrate may be fibrous. Starting with a porous SiO₂ substrate may provide advantageous such as reduced cost and mechanical flexibility and/or durability. However, the starting substrate may just as well be porous silicon which would not be stripped of oxygen as is the case with a porous SiO₂ substrate.

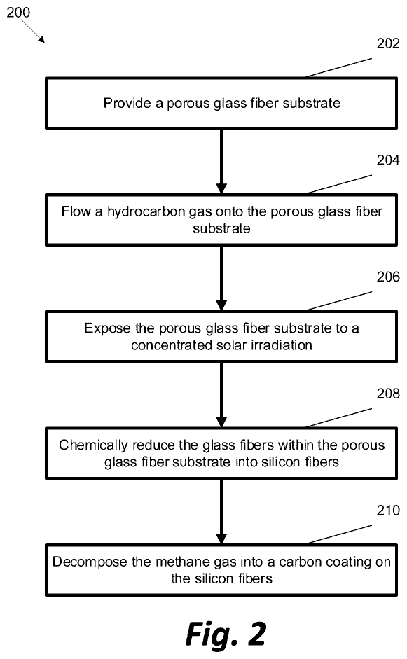

FIG. 2 is a flowchart illustrating an example process for producing silicon fibers coated with graphite in accordance with an embodiment of the invention. The process 200 includes providing (202) a porous glass fiber substrate. The porous glass fiber substrate includes silica, silicon dioxide (SiO₂), or quartz. In some examples, the porous glass fiber substrate may be pre-processed with glass or silicon particles before being coated with carbon. The particles may be nano-particles or micro-particles. The particles may be loosely attached to the fibers by Van der Waals forces. The chemical reduction and high temperatures may fuse (e.g. bond) them to the fibers. During the carbon coating process, the particles may be conformally coated with graphite.

The process 200 further includes flowing (204) a hydrocarbon gas onto the porous glass fiber substrate. The hydrocarbon gas may be a methane gas. The methane gas may include a chemical formula of CH₄. The process 200 further includes exposing (206) the porous glass fiber substrate to a concentrated light irradiation. The concentrated light irradiation may be a concentrated solar irradiation. The concentrated light irradiation may be produced by a solar concentrator which may have the capability of producing controllable radiative heat flux up to 4500 suns, which may be sufficient to bring reactor operating temperatures above 1500 K. This concentrated solar irradiation is described in greater detail in Int. Pub. No. 2022/236303 which has been incorporated by reference previously.

The concentrated solar irradiation may chemically reduce (208) at least a portion of the glass fibers within the porous glass fiber substrate into silicon fibers. The glass fibers within the porous glass fiber substrate chemically reduce, producing a product stream of predominantly water vapor, unreacted methane, other intermediate hydrocarbons, and solid silicon fibers (e.g., deoxygenated glass fibers). As the reduction reaction ceases, the methane gas may decompose (210) into a solid carbon coating the silicon fibers. In some embodiments, the coated silicon fibers may be advantageously utilized to produce a fibrous core-shell silicon-graphite battery anode.

In some embodiments, a concentrated solar irradiation (e.g. concentration factor 100 or greater) may be used in a process that converts inexpensive glass fibers to silicon fibers that are subsequently and seamlessly coated to protect them. The silicon fibers may be coated with graphite.

In some embodiments, pure methane or a methane-carrier gas mixture (e.g., hydrogen as carrier gas) may be converted into a graphite coating on silicon.

In some embodiments, a gaseous hydrocarbon may be flowed onto the substrate. The gaseous substrate may be methane or a biogas.

In some embodiments, the carrier gas (e.g., hydrogen) may be the only gas present during the reduction reaction, followed by the introduction of methane for carbon deposition onto the silicon fibers.

In some embodiments, the porous glass fiber substrate may include glass felt, weave, and/or perforation. As discussed above, the starting substrate may be a porous silicon substrate.

In some embodiments, the light source may augment actual solar incidence (e.g., in an outdoor setting) with a supplemental artificial light source (e.g., xenon arc lamp) to control for ordinary variations in solar flux while maintaining approximately constant irradiation. For example, a secondary concentrated solar power source may be utilized.

In some embodiments, heating from the light source may be augmented with a secondary non-optical heater. For example, a Joule heater may be utilized to supplement the heat from the light source. The heating from the light source may also be augmented with heating from another light source.

In some embodiments, the porous glass fiber substrate may be a roll-to-roll substrate which is capable of allowing for fresh porous substrate to be introduced to the process continuously, and solid reaction products extracted on the roll-to-roll substrate. The processed substrate may be used in the manufacture of electrochemical energy storage devices.

The concentrated solar irradiation may be produced utilizing a concentrator which may include one or more types of reflectors (e.g. elliptical, parabolic, compound). The artificial light source may include one or more types of bulbs (e.g. plasma arc, halogen, LED, fluorescent). The reaction may be performed in a reaction chamber. A reaction zone may be housed within the reaction chamber.

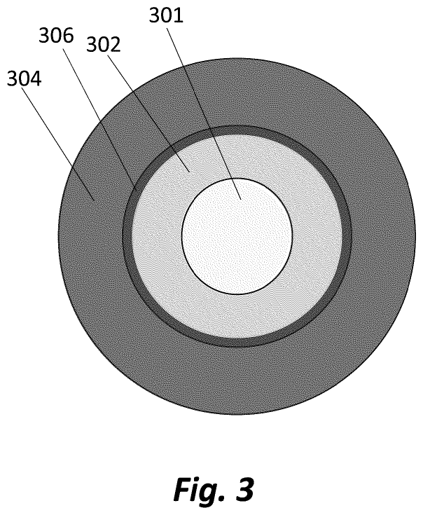

FIG. 3 is a schematic cross-sectional view of an example silicon fiber coated with graphite in accordance with an embodiment of the invention. As discussed above, the SiO₂ fibers are stripped of oxygen and thus converted into Si fibers. A SiO₂ portion 301 may still remain as the core of the Si fiber. Thus, the Si portion 302 may be an annular coating which surrounds a remaining SiO₂ portion 301. While the SiO₂ portion 301 is illustrated as a remaining cylindrical member, the SiO₂ portion 301 may be other shapes such as an oval shape. Further, the Si portion 302 may be interspersed within the SiO₂ portion 301.

The illustrated silicon portion 302 is a cylindrical annular shaped member which is coated with an annular coating of carbon 304. The carbon 304 may be graphitic carbon and may be formed in layers which may be seen in the images included and discussed below. At the interface of the carbon coating 304 and the silicon portion 302 may be a silicon-carbide (SiC) layer 306. The SiC layer 306 may mediate changes in thermal and mechanical behavior during operation as an anode of a battery. During deposition of the carbon, the outside silicon portions of the silicon portion 302 may combine with the carbon to form the SiC layer 306 at the interface of the carbon 304 and the silicon portion 302.

While it is illustrated that a residual SiO₂ fiber 301 is present, it has as well been discovered that this the process may be altered to produce full conversion of the SiO₂ fiber into silicon and thus the residual SiO₂ fiber 301 is exemplary of processes that include the residual SiO₂ fiber. While the residual SiO₂ fiber 301 is illustrated to be large in respect to the silicon portion 302, the process may make the residual SiO₂ fiber 301 larger or smaller when compared to the silicon portion 302.

This structure may be utilized in battery technology including in the anode of a battery. As discussed above, a battery including an anode including a carbon-based coating may advantageous. The carbon-based coating may be implemented on a silicon fiber which may improve the Li-ion storage because silicon has demonstrated increased Li-ion storage capabilities when compared to carbon. In examples with the residual SiO₂ fiber 301, the SiO₂ fiber 301 also has increased Li-ion storage capabilities when compared to pure carbon. The carbon-based coating may provide increased thermal and electrical conductivity when compared to a silicon-only anode. The carbon-based coating may be high quality graphitic carbon which has been shown to have increased Li ion storage capacity, thermal conductivity, and electrical conductivity when even compared to ordinary carbon.

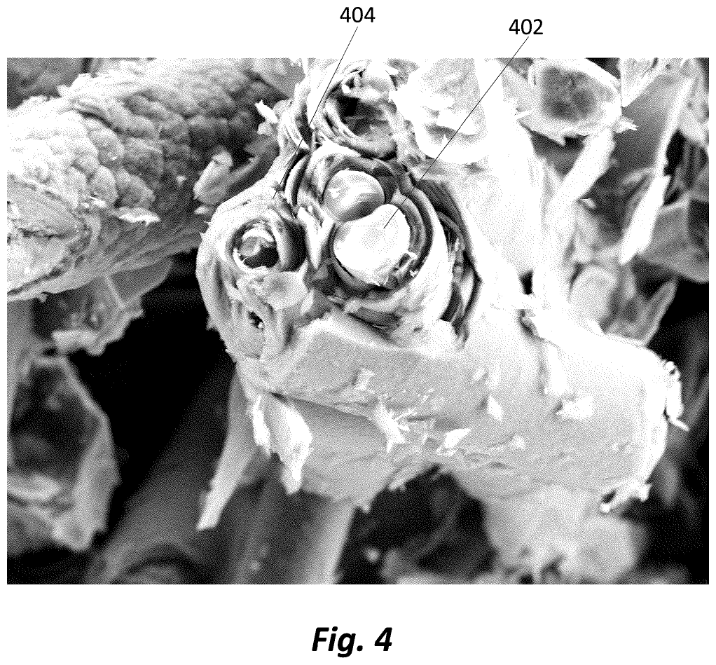

FIG. 4 is a scanning electron microscope (SEM) image of a processed porous glass substrate. The processed substrate includes a core 402. The core 402 may include a combination of silicon and SiO₂. As described in FIG. 3, the core 402 may include residual SiO₂ and a silicon portion. The core 402 may be surrounded by a carbon coating 404. As illustrated, the carbon coating 404 may be layered on top of the core 402. It has been observed that the manufactured carbon coating 404 is a graphite that is cylindrical. The carbon coating 404 may be graphene layers formed concentrically around the core 404 (e.g. the fiber). This type of graphitic layers has not been observed previously other than in multi-walled carbon nanotubes include hollow cores and are universally much smaller in diameter. Such a layered graphitic structure has been especially advantageous in the production of and utilization in anodes of Li-ion batteries.

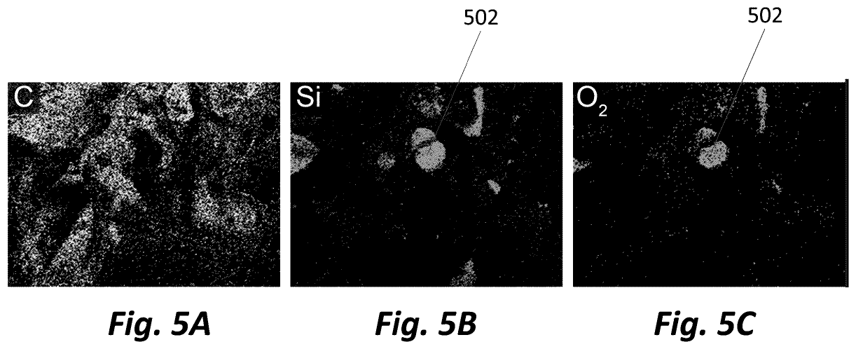

FIGS. 5A, 5B, and 5C illustrate various energy dispersed spectroscopy (EDS) images of the processed porous glass substrate illustrated in FIG. 4. The EDS images analyze the processed porous glass substrate for different chemical compositions. FIG. 5A illustrates the analysis for carbon. As illustrated, the carbon is pervasive throughout the processed porous glass substrate. FIG. 5B illustrates the analysis for silicon. As illustrated, silicon is present in a core area 502. FIG. 5C illustrates the analysis for SiO₂. As illustrated, the SiO₂ is present in the core area 502.

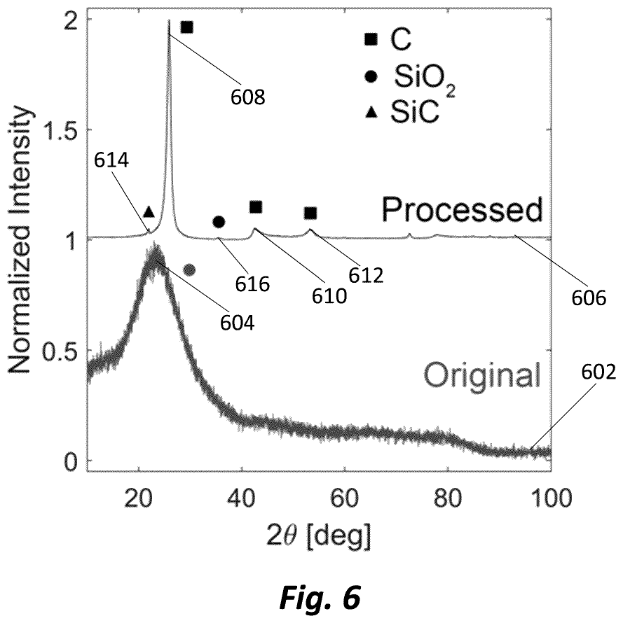

FIG. 6 is two example X-ray diffraction (XRD) plot on the processed porous glass substrate illustrated in FIG. 4 and the unprocessed porous glass substrate. The bottom plot 602 is the XRD plot of the unprocessed porous glass substrate. There is a single peak 604 which corresponds to the level of SiO₂. The bottom XRD plot shows a high content of SiO₂ and no other peaks corresponding to the presence of other elements. The top plot 606 is the XRD plot of the processed porous glass substrate. The top plot 606 includes a high peak 608 and two smaller peaks 610, 612 which corresponds to a high amount of crystalline carbon. The top plot 606 also includes a small peak 614 which corresponds to an amount of SiC. The top plot 606 also includes a small peak 616 which corresponds to an amount of SiO₂. While the top plot 606 does not have a sharp XRD peak corresponding to the silicon due to the presence of amorphous silicon rather than crystalline silicon, it does have a broad shoulder centered around 25 degrees. The background of the XRD spectrum was subtracted which decreases the presence of this broad shoulder corresponding to the amorphous silicon from the top plot 606.

Thus, the bottom plot 602 shows that the unprocessed porous glass substrate originally includes a high amount of SiO₂. The top plot 606 shows that the processed porous glass substrate includes a high amount of crystalline carbon.

In some examples, the porous substrate (e.g. porous glass substrate or porous silicon substrate) may be pre-processed with glass or silicon particles before being coated with carbon. The particles may be nano-particles or micro-particles. The particles may be loosely attached to the fibers by Van der Waals forces. The chemical reduction and high temperatures may fuse (e.g. bond) them to the fibers. During the carbon coating process, the particles may be conformally coated with graphite.

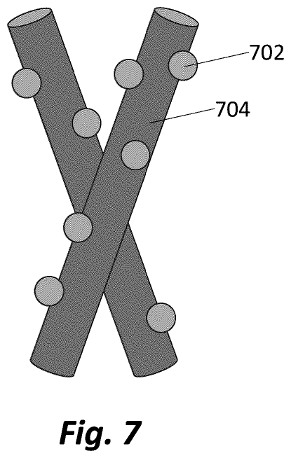

FIG. 7 illustrates an example schematic of glass fibers before carbon deposition which have been pre-processed by glass or silicon particles in accordance with an embodiment of the invention. As illustrated, the glass or silicon particles 702 may be adhered to the glass fibers 704. During carbon deposition, the glass or silicon particles 702 may be incorporated into the carbon coating. The glass or silicon particles 702 may increase the Li-ion capacity of the anode when the resultant structure is incorporated into the battery. The inclusion of the glass or silicon particles 702 in the carbon coating may provide increased Li-ion capacity while still including advantageous high electrical and thermal conductivity of the carbon coating as discussed above.

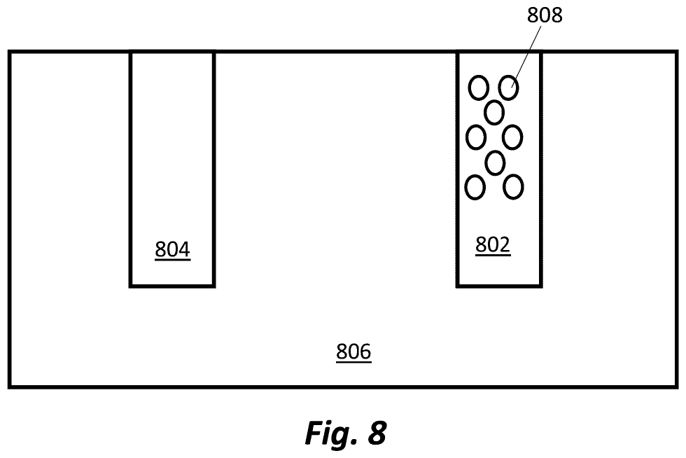

FIG. 8 schematically illustrates an example battery in accordance with an embodiment of the invention. The battery 806 includes an anode 802 and a cathode 804 which is electrically separated from the anode. The anode 802 stores Li-ions 808. In operation, the Li-ions 808 flow from the anode 802 to the cathode 804 to produce a current. The anode 802 may include the processed carbon coated silicon fibers as discussed above. The processed carbon coated silicon fibers may provide advantages as discussed above such as higher Li-ion uptake and increased electrical and thermal conductivity.

Although only a few embodiments of the invention have been described in detail, it should be appreciated that the invention may be implemented in many other forms without departing from the spirit or scope of the invention. For example, embodiments such as enumerated below are contemplated:

Clause 1. A method of coating a porous glass substrate, the method comprising: providing a porous glass substrate; flowing gaseous hydrocarbon onto a porous glass substrate in a reaction zone; and exposing the porous glass substrate to a concentrated solar irradiation in the reaction zone such that the porous substrate and gases surrounding the porous substrate absorb the concentrated solar irradiation producing heat, wherein the heat chemically reduces glass fibers in the porous glass substrate into silicon fibers, and wherein the heat decomposes the gaseous hydrocarbon into a carbon coating on the silicon fibers.

Clause 2. The method of clause 1, wherein the heat decomposes the gaseous hydrocarbon into hydrogen gas and carbon.

Clause 3. The method of clause 2, wherein the concentrated solar irradiation causes photocatalysis which accelerates the decomposition of the gaseous hydrocarbon into hydrogen gas and carbon.

Clause 4. The method of clause 1, wherein the concentrated solar irradiation has a concentration factor of 100 or greater.

Clause 5. The method of clause 1, wherein the gaseous hydrocarbon is high purity methane gas.

Clause 6. The method of clause 1, wherein the gaseous hydrocarbon is a biogas.

Clause 7. The method of clause 1, wherein the gaseous hydrocarbon comprises a carrier gas mixed with methane or biogas.

Clause 8. The method of clause 7, wherein the carrier gas is hydrogen gas, nitrogen gas, and/or argon gas.

Clause 9. The method of clause 1, wherein the carbon comprises graphene, graphite, carbon nanotubes, or carbon black which is deposited conformally onto the surfaces of the silicon fibers.

Clause 10. The method of clause 9, wherein the conformal carbon coating from adjacent elements or ligaments of the porous substrate coalesce to form a continuous structure.

Clause 11. The method of clause 9, wherein, after the carbon is deposited onto the porous substrate, the porous substrate is used to manufacture electrochemical energy storage devices.

Clause 12. The method of clause 1, wherein the concentrated solar irradiation comprises solar light from the sun.

Clause 13. The method of clause 1, wherein the concentrated solar irradiation comprises solar light from the sun augmented with an artificial light source.

Clause 14. The method of clause 13, further comprising optimizing the amount of augmented artificial light from the artificial light source to keep a constant amount of irradiation.

Clause 15. The method of clause 13, wherein the artificial light source comprises a plasma arc lamp, a halogen bulb, an LED, a fluorescent bulb, metal halide lamp, or argon lamp.

Clause 16. The method of clause 13, wherein the artificial light source comprises a xenon arc lamp.

Clause 17. The method of clause 13, wherein the concentrated solar irradiation comprises the solar light from the sun during a time when the sun is irradiating light into concentrators that concentrate the sun light into the reaction zone and the concentrated solar irradiation comprises artificial light when the sun is not irradiating light into the concentrators.

Clause 18. The method of clause 1, wherein the concentrated solar irradiation comprises light from an artificial light source.

Clause 19. The method of clause 1, wherein the porous glass substrate comprises a roll to roll substrate.

Clause 20. The method of clause 19, further comprising operating the roll to roll substrate to continually maintain fresh porous glass substrate.

Clause 21. The method of clause 1, wherein the porous glass substrate comprises silica cloth or felt.

Clause 22. The method of clause 1, further comprising concentrating a solar light source using a reflector.

Clause 23. The method of clause 22, wherein the reflector comprises an elliptical reflector, a parabolic reflector, a compound reflector, a Fresnel lens, and/or an array of flat reflectors.

Clause 24. The method of clause 22, wherein the reflector comprises a variable reflector which adjusts the amount of concentrated solar irradiation in the reaction zone.

Clause 25. The method of clause 1, wherein the reaction zone is housed within a reaction chamber.

Clause 26. The method of clause 1, wherein the exposing the gaseous hydrocarbon to the concentrated solar irradiation occurs in multiple directions.

Clause 27. The method of clause 1, wherein the gaseous hydrocarbon comprises natural gas.

Clause 28. The method of clause 1, further comprising: reflowing an output gas onto the porous glass substrate in the reaction zone; and exposing the porous glass substrate to a concentrated solar irradiation in the reaction zone such that the reflowed gas further decomposes into hydrogen gas and carbon.

Clause 29. The method of clause 1, further comprising pre-processing the porous glass substrate by adhering silicon or glass particles to the glass fibers, wherein the silicon or glass particles are incorporated into the carbon coating on the silicon fibers after exposure to the concentrated solar irradiation.

Clause 30. The method of clause 29, wherein the silicon or glass particles are nano-particles or micro-particles.

Clause 31. The method of clause 1, wherein the carbon coating comprises cylindrical concentric layers of carbon which are concentrically layered on top of one another in a repeating pattern.

Clause 32. The method of clause 1, wherein the silicon fibers comprise silicon dioxide and silicon.

Clause 33. The method of clause 32, wherein the silicon fibers comprise a silicon dioxide core with a silicon annulus surrounding the silicon dioxide core.

Clause 34. The method of clause 33, wherein the silicon annulus forms a shell around the silicon dioxide core.

Clause 35. The method of clause 1, wherein the silicon fibers comprise solid silicon fibers.

Clause 36. A method of coating a porous glass substrate, the method comprising: providing a porous glass substrate; flowing a carrier gas onto a porous glass substrate in a reaction zone; exposing the porous glass substrate to a concentrated solar irradiation in the reaction zone such that the porous substrate and gases surrounding the porous substrate absorb the concentrated solar irradiation producing heat, wherein the heat chemically reduces glass fibers in the porous glass substrate into silicon fibers; as the reduction reaction ceases: flowing a gaseous hydrocarbon onto the silicon fibers; and exposing the silicon fibers to the concentrated solar irradiation such that the silicon fibers and the gases surrounding the silicon fibers absorb the concentrated solar irradiation to produce heat, wherein the heat decomposes the gaseous hydrocarbon into a carbon coating on the silicon fibers.

Clause 37. The method of clause 36, wherein the heat decomposes the gaseous hydrocarbon into hydrogen gas and carbon.

Clause 38. The method of clause 37, wherein the concentrated solar irradiation causes photocatalysis which accelerates the decomposition of the gaseous hydrocarbon into hydrogen gas and carbon.

Clause 39. The method of clause 36, wherein the concentrated solar irradiation has a concentration factor of 100 or greater.

Clause 40. The method of clause 36, wherein the gaseous hydrocarbon is high purity methane gas.

Clause 41. The method of clause 36, wherein the gaseous hydrocarbon is a biogas.

Clause 42. The method of clause 36, wherein the gaseous hydrocarbon comprises a carrier gas mixed with methane or biogas.

Clause 43. The method of clause 42, wherein the carrier gas is hydrogen gas.

Clause 44. The method of clause 36, wherein the carbon comprises graphene, graphite, carbon nanotubes, or carbon black which is deposited conformally onto the surfaces of the silicon fibers.

Clause 45. The method of clause 44, wherein the conformal carbon coating from adjacent elements or ligaments of the porous substrate coalesce to form a continuous structure.

Clause 46. The method of clause 44, wherein, after the carbon is deposited onto the porous substrate, the porous substrate is used to manufacture electrochemical energy storage devices.

Clause 47. The method of clause 46, wherein the porous substrate is used to manufacture an anode of a lithium ion battery.

Clause 48. The method of clause 36, wherein the concentrated solar irradiation comprises solar light from the sun.

Clause 49. The method of clause 36, wherein the concentrated solar irradiation comprises solar light from the sun augmented with an artificial light source.

Clause 50. The method of clause 49, further comprising optimizing the amount of augmented artificial light from the artificial light source to keep a constant amount of irradiation.

Clause 51. The method of clause 49, wherein the artificial light source comprises a plasma arc lamp, a halogen bulb, an LED, a fluorescent bulb, metal halide lamp, or argon lamp.

Clause 52. The method of clause 49, wherein the artificial light source comprises a xenon arc lamp.

Clause 53. The method of clause 49, wherein the concentrated solar irradiation comprises the solar light from the sun during a time when the sun is irradiating light into concentrators that concentrate the sun light into the reaction zone and the concentrated solar irradiation comprises artificial light when the sun is not irradiating light into the concentrators.

Clause 54. The method of clause 36, wherein the concentrated solar irradiation comprises light from an artificial light source.

Clause 55. The method of clause 36, wherein the porous glass substrate comprises a roll to roll substrate.

Clause 56. The method of clause 55, further comprising operating the roll to roll substrate to continually maintain fresh porous glass substrate.

Clause 57. The method of clause 36, wherein the porous glass substrate comprises silica cloth or felt.

Clause 58. The method of clause 36, further comprising concentrating a solar light source using a reflector.

Clause 59. The method of clause 58, wherein the reflector comprises an elliptical reflector, a parabolic reflector, a compound reflector, a Fresnel lens, and/or an array of flat reflectors.

Clause 60. The method of clause 58, wherein the reflector comprises a variable reflector which adjusts the amount of concentrated solar irradiation in the reaction zone.

Clause 61. The method of clause 36, wherein the reaction zone is housed within a reaction chamber.

Clause 62. The method of clause 36, wherein the exposing the gaseous hydrocarbon to the concentrated solar irradiation occurs in multiple directions.

Clause 63. The method of clause 36, wherein the gaseous hydrocarbon comprises natural gas.

Clause 64. The method of clause 36, further comprising: reflowing an output gas onto the porous glass substrate in the reaction zone; and exposing the porous glass substrate to a concentrated solar irradiation in the reaction zone such that the reflowed gas further decomposes into hydrogen gas and carbon.

Clause 65. The method of clause 36, further comprising pre-processing the porous glass substrate by adhering silicon or glass particles to the glass fibers, wherein the silicon or glass particles are incorporated into the carbon coating on the silicon fibers after exposure to the concentrated solar irradiation.

Clause 66. The method of clause 65, wherein the silicon or glass particles are nano-particles or micro-particles.

Clause 67. The method of clause 36, wherein the carbon coating comprises cylindrical concentric layers of carbon which are concentrically layered on top of one another in a repeating pattern.

Clause 68. The method of clause 36, wherein the silicon fibers comprise silicon dioxide and silicon.

Clause 69. The method of clause 68, wherein the silicon fibers comprise a silicon dioxide core with a silicon shell.

Clause 70. The method of clause 36, wherein the silicon fibers comprise solid silicon fibers.

Clause 71. An anode for a lithium ion battery comprising a plurality of silicon fibers which are coated by a carbon coating.

Clause 72. The anode of clause 71, wherein the silicon fibers comprise silicon dioxide and silicon.

Clause 73. The anode of clause 72, wherein the silicon fibers comprise a silicon dioxide core with a silicon annulus surrounding the silicon dioxide core.

Clause 74. The anode of clause 73, wherein the silicon annulus forms a shell around the silicon dioxide core.

Clause 75. The anode of clause 71, wherein a silicon-carbide material is at the interface between the silicon fibers and the carbon coating.

Clause 76. The anode of clause 71, wherein the carbon coating includes silicon or glass particles.

Clause 77. The anode of clause 76, wherein the silicon or glass particles are nano-particles or micro-particles.

Clause 78. The anode of clause 71, wherein the silicon fibers comprise solid silicon fibers.

Clause 79. The anode of clause 71, wherein the carbon coating comprises cylindrical concentric layers of carbon which are concentrically layered on top of one another in a repeating pattern.

Clause 80. The anode of clause 71, wherein the silicon fibers comprise amorphous silicon.

Clause 81. The anode of clause 71, wherein the anode combines with a cathode separated from the anode to form a lithium ion battery.

### DOCTRINE OF EQUIVALENTS

While the above description contains many specific embodiments of the invention, these should not be construed as limitations on the scope of the invention, but rather as an example of one embodiment thereof. It is therefore to be understood that the present invention may be practiced in ways other than specifically described, without departing from the scope and spirit of the present invention. Thus, embodiments of the present invention should be considered in all respects as illustrative and not restrictive. Accordingly, the scope of the invention should be determined not by the embodiments illustrated, but by the appended claims and their equivalents.

What is claimed is:

1. A method of coating a porous glass substrate, the method comprising:
providing a porous glass substrate;
flowing gaseous hydrocarbon onto a porous glass substrate in a reaction zone; and
exposing the porous glass substrate to a concentrated solar irradiation in the reaction zone such that the porous substrate and gases surrounding the porous substrate absorb the concentrated solar irradiation producing heat,
wherein the heat chemically reduces glass fibers in the porous glass substrate into silicon fibers, and
wherein the heat decomposes the gaseous hydrocarbon into a carbon coating on the silicon fibers.

2. The method of claim 1, wherein the heat decomposes the gaseous hydrocarbon into hydrogen gas and carbon.

3. The method of claim 2, wherein the concentrated solar irradiation causes photocatalysis which accelerates the decomposition of the gaseous hydrocarbon into hydrogen gas and carbon.

4. The method of claim 1, wherein the porous glass substrate comprises a roll to roll substrate.

5. The method of claim 1, wherein the porous glass substrate comprises silica cloth or felt.

6. The method of claim 1, wherein the gaseous hydrocarbon is high purity methane gas.

7. The method of claim 1, wherein the carbon comprises graphene, graphite, carbon nanotubes, or carbon black which is deposited conformally onto the surfaces of the silicon fibers.

8. The method of claim 7, wherein the conformal carbon coating from adjacent elements or ligaments of the porous substrate coalesce to form a continuous structure.

9. The method of claim 1, wherein, after the carbon is deposited onto the porous substrate, the porous substrate is used to manufacture electrochemical energy storage devices.

10. An anode for a lithium ion battery comprising a plurality of silicon fibers which are coated by a carbon coating.

11. The anode of claim 10, wherein the silicon fibers comprise silicon dioxide and silicon.

12. The anode of claim 11, wherein the silicon fibers comprise a silicon dioxide core with a silicon annulus surrounding the silicon dioxide core.

13. The anode of claim 12, wherein the silicon annulus forms a shell around the silicon dioxide core.

14. The anode of claim 10, wherein a silicon-carbide material is at the interface between the silicon fibers and the carbon coating.

15. The anode of claim 10, wherein the carbon coating includes silicon or glass particles.

16. The anode of claim 15, wherein the silicon or glass particles are nano-particles or micro-particles.

17. The anode of claim 10, wherein the silicon fibers comprise solid silicon fibers.

18. The anode of claim 10, wherein the carbon coating comprises cylindrical concentric layers of carbon which are concentrically layered on top of one another in a repeating pattern.

19. The anode of claim 10, wherein the silicon fibers comprise amorphous silicon.

20. The anode of claim 10, wherein the anode combines with a cathode separated from the anode to form a lithium ion battery.
